(19) United States
(12) Patent Application Publication
(10) Pub. No.: US 2018/0276470 A1
(43) Pub. Date: Sep. 27, 2018

(54) MEASURING SYSTEM AND METHOD FOR DISPLAYING A LIVE VIEW OF A MEASUREMENT SETUP SUPERIMPOSED ON MEASUREMENT RESULTS

(71) Applicant: Rohde & Schwarz GmbH & Co. KG, Munich (DE)

(72) Inventor: Philip DIEGMANN, Munich (DE)

(21) Appl. No.: 15/466,957

(22) Filed: Mar. 23, 2017

(51) Int. Cl. G06K 9/00; G01R 31/28; G01R 1/067; G06T 11/60; G06F 3/16; G06K 7/14

(52) U.S. Cl. CPC G06K 9/00671; G01R 31/28; G01R 1/067; H04W 88/02; G06F 3/167; G06K 7/146; G06K 7/1413; G06T 11/60

(57) ABSTRACT

A measuring system comprises a measuring device for measuring data with respect to a measurement setup comprising circuits with the aid of a probe, and at least one mobile device wirelessly connected to the measuring device, wherein the at least one mobile device displays a live view of the measurement setup superimposed on at least one measurement result of the measuring device.

### TECHNICAL FIELD

The invention relates to a measuring system and a measuring method for displaying a live view of a measurement setup superimposed on measurement results.

### BACKGROUND

Generally, in times of an increasing number of electrical circuits applied in many different applications, there is a growing need of a measuring system and a method for measuring data with respect to these circuits in a most efficient manner in order to allow for a highly performant and low-cost test equipment for testing the correct functionality of said circuits.

Germany patent publication number DE102015204780A1 relates to an electronic eyeglasses for the usage with an electrical or electronic measuring device. Disadvantageously, even though the measuring person already wears said eyeglasses, the measuring person however has to look at the visual display device first, and then to the respective measurement setup or the other way round, which makes the process of measuring inefficient.

Accordingly, there is a need for an approach for displaying a live view of a measurement setup superimposed on measurement results.

### SOME EXAMPLE EMBODIMENTS

Embodiments of the present invention advantageously address the foregoing requirements and needs, as well as others, by providing a measuring system and a measuring method for displaying a live view of a measurement setup superimposed on measurement results.

According to a first aspect of the invention, a measuring system is provided. The measuring system comprises a measuring device for measuring data with respect to a measurement setup, and at least one mobile device connected to the measuring device. The at least one mobile device displays a live view of the measurement setup superimposed on at least one measurement result of the measuring device. Advantageously, this allows for doing the measurement without firstly having to look at the measuring device and then to the measurement setup. Further advantageously, the measuring device has not be equipped with a display, which saves costs.

According to a first implementation form of the first aspect, the at least one mobile device comprises a mobile phone, a tablet computer, any kind of virtual or augmented reality device such as virtual reality glasses or augmented reality glasses, or a combination thereof.

According to a further implementation form of the first aspect, the connection between the measuring device and the at least one mobile device is a wireless connection.

According to a further implementation form of the first aspect, the at least one mobile device recognizes or marks at least one probe of the measuring device in the displayed live view of the measurement setup superimposed on the at least one measurement result of the measuring device.

According to a further implementation form of the first aspect, the at least one mobile device associates the at least one probe of the measuring device with at least one corresponding measurement result of the measurement results of the measuring device. Advantageously, this allows for easily finding the correct location, where to connect the probe and for observing the execution of the measurement.

According to a further implementation form of the first aspect, the measuring device comprises geolocation means for determining a recent position. This is particularly advantageous with respect to interference hunting, finding a source of emission, or when measuring several base stations in a row.

According to a further implementation form of the first aspect, the at least one mobile device comprises geolocation means for determining a recent position. As already mentioned above, this is particularly advantageous with respect to interference hunting, finding a source of emission, or when measuring several base stations in a row.

According to a further implementation form of the first aspect, the measuring device comprises voice control means for controlling at least one function of the measuring device by voice. Advantageously, the measurement setup can be operated without touching any switches or the like.

According to a further implementation form of the first aspect, the at least one mobile device comprises voice control means for controlling at least one function of the at least one mobile device or at least one function of the measuring device. As already mentioned above, this is particularly advantageous because in this manner, the measurement setup can be operated without touching any switches or the like.

According to a second aspect of the invention, a measuring method is provided. The measuring method comprises the steps of measuring data with respect to a measurement setup with the aid of a measuring device, and displaying a live view of the measurement setup superimposed on at least one measurement result of the measuring device with the aid of at least one mobile device connected to the measuring device. Advantageously, this allows for doing the measurement without firstly having to look at the measuring device and then to the measurement setup. Further advantageously, the measuring device has not be equipped with a display, which saves costs.

According to a first implementation form of the second aspect, the at least one mobile device comprises a mobile phone, a tablet computer, any kind of virtual or augmented reality device such as virtual reality glasses or augmented reality glasses, or a combination thereof.

According to a further implementation form of the second aspect, the connection between the measuring device and the at least one mobile device is a wireless connection.

According to a further implementation form of the second aspect, the measuring method further comprises the step of recognizing or marking at least one probe of the measuring device in the displayed live view of the measurement setup superimposed on the at least one measurement result of the measuring device.

According to a further implementation form of the second aspect, the measuring method further comprises the step of associating the at least one probe of the measuring device with at least one corresponding measurement result of the at least one measurement result of the measuring device. Advantageously, this allows for easily finding the correct location, where to connect the probe and for observing the execution of the measurement.

According to a further implementation form of the second aspect, the measuring method further comprises the step of determining a recent position with the aid of the measuring device comprising geolocation means. This is particularly advantageous with respect to interference hunting, finding a source of emission, or when measuring several base stations in a row.

According to a further implementation form of the second aspect, the measuring method further comprises the step of determining a recent position with the aid of the at least one mobile device comprising geolocation means. As already mentioned above, this is particularly advantageous with respect to interference hunting, finding a source of emission, or when measuring several base stations in a row.

According to a further implementation form of the second aspect, the measuring method further comprises the step of controlling at least one function of the measuring device by voice with the aid of the measuring device comprising voice control means. Advantageously, the measurement setup can be operated without touching any switches or the like.

According to a further implementation form of the second aspect, the measuring method further comprises the step of controlling at least one function of the at least one mobile device or of the measuring device by voice with the aid of the at least one mobile device comprising voice control means. As already mentioned above, this is particularly advantageous because in this manner, the measurement setup can be operated without touching any switches or the like.

Still other aspects, features, and advantages of the present invention are readily apparent from the following detailed description, simply by illustrating a number of particular embodiments and implementations, including the best mode contemplated for carrying out the present invention. The present invention is also capable of other and different embodiments, and its several details can be modified in various obvious respects, all without departing from the spirit and scope of the present invention. Accordingly, the drawings and description are to be regarded as illustrative in nature, and not as restrictive.

### BRIEF DESCRIPTION OF THE DRAWINGS

Embodiments of the present invention are illustrated by way of example, and not by way of limitation, in the figures of the accompanying drawings, in which like reference numerals refer to similar elements, and in which:

FIG. 1 shows a block diagram of a measuring system according to example embodiments of the present invention;

FIG. 2 shows an example probe with bar code; and

FIG. 3 shows a flow chart depicting a measuring method according to example embodiments of the present invention.

### DETAILED DESCRIPTION

A measuring system and a measuring method for displaying a live view of a measurement setup superimposed on measurement results are described. In the following description, for the purposes of explanation, numerous specific details are set forth in order to provide a thorough understanding of the invention. It is apparent, however, that the invention may be practiced without these specific details or with an equivalent arrangement. In other instances, well-known structures and devices are shown in block diagram form in order to avoid unnecessarily obscuring the invention.

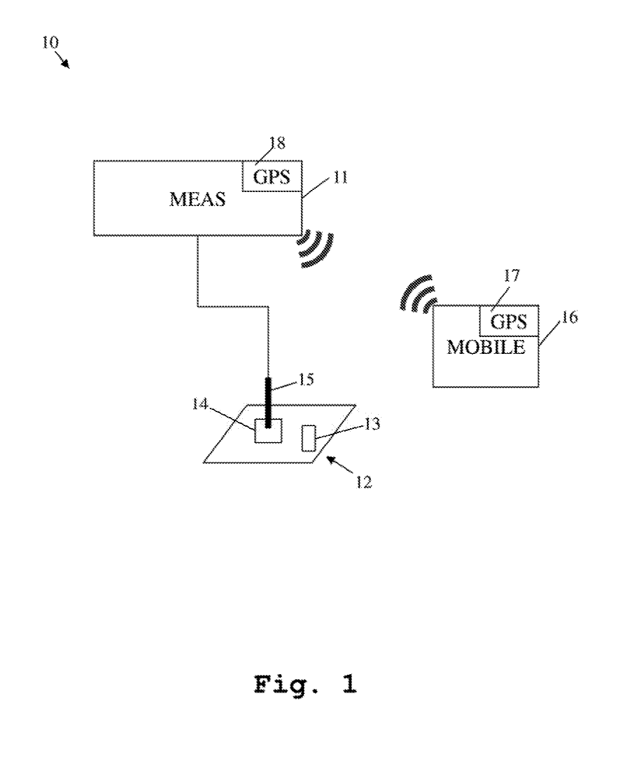

FIG. 1 illustrates a block diagram of a measuring system 10 according to example embodiments of the present invention.

According to FIG. 1, the measuring system comprises a measuring device 11 for measuring data with respect to a measurement setup 12 exemplarily comprising two circuits 13, 14 with the aid of a probe 15 connected to the measuring device 11. In addition to this, the measuring system 10 comprises a mobile device 16 which is wirelessly connected to the measuring device 11.

Furthermore, the mobile device 16 displays a live view of the measurement setup 12 superimposed on at least one measurement result of the measuring device 11 with the aid of a display. In other words, what the user sees, either through his own eyes or via projection inside the device like a head up display, is superimposed on at least one measurement result and displayed with the aid of the display of the mobile device 16.

In this context, the mobile device 16 may comprise a mobile phone, a tablet computer, any kind of virtual or augmented reality device such as virtual reality glasses or augmented reality glasses, or a combination thereof.

Additionally, the mobile device 16 may comprise a camera for showing a live picture of the measurement setup 12.

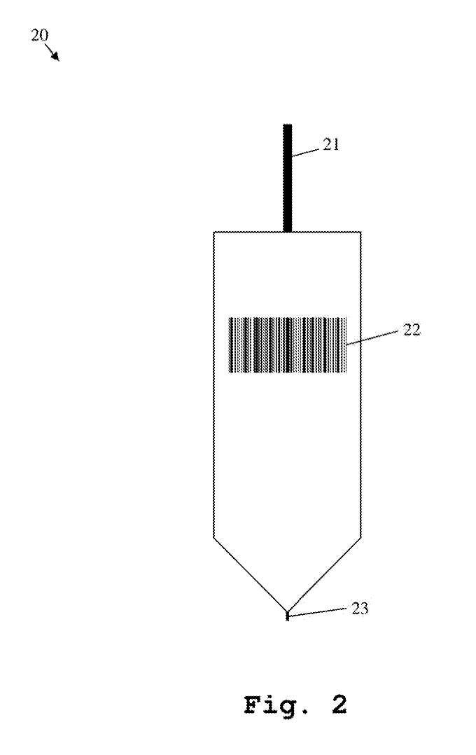

Moreover, the mobile device 16 recognizes or marks the probe 15 of the measuring device 11 in the displayed live view of the measurement setup 12 superimposed on the at least one measurement result of the measuring device 11. In this context, the probe 15 advantageously comprises an optical pattern such as a bar code or a quick response (QR) code in order to allow for an efficient recognition or marking, respectively. This is shown in FIG. 2 for the bar code.

In addition to this, the mobile device 16 associates the probe 15 of the measuring device 11 with at least one corresponding measurement result of the measurement results of the measuring device.

Furthermore, the mobile device 16 may comprise geolocation means 17 such as global positioning system (GPS) for determining a recent position. The mobile device 16 may further comprise voice control means for controlling at least one function of the mobile device 16 or at least one function of the measuring device 11 by voice.

Additionally or alternatively, the measuring device 11 may comprise geolocation means 18 such as GPS for determining a recent position. Likewise additionally or alternatively, the measuring device 11 may comprise voice control means for controlling at least one function of the measuring device 11 by voice.

FIG. 2 shows an example probe 20 with bar code 22. The illustrated probe 20 comprises a connection cable 21 for connecting it to the measuring device 11, a bar code 22 for allowing for the above-mentioned efficient recognition or marking, and a probe tip 23 for exactly contacting to the circuits 13, 14 of the measurement setup 12.

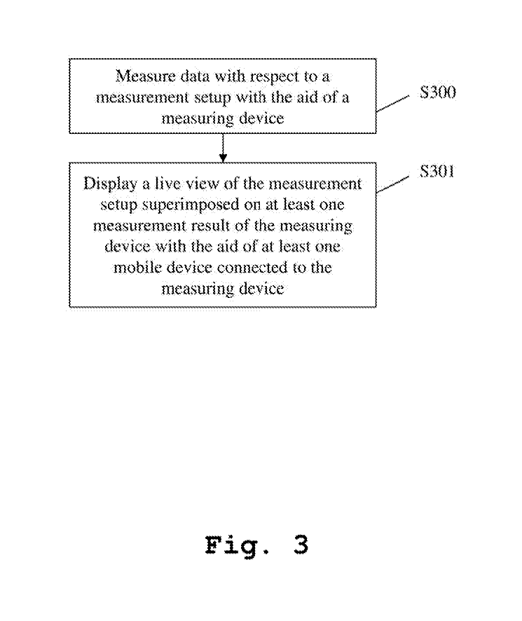

FIG. 3 shows a flow chart depicting a measuring method according to example embodiments of the present invention. In a first step S300, data with respect to a measurement setup with the aid of a measuring device is measured. Then, in a second step S301, a live view of the measurement setup superimposed on at least one measurement result of the measuring device is displayed with the aid of at least one mobile device connected to the measuring device.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

What is claimed is:

1. A measuring system comprising:
a measuring device for measuring data with respect to a measurement setup, and
at least one mobile device connected to the measuring device,
wherein the at least one mobile device displays a live view of the measurement setup superimposed on at least one measurement result of the measuring device.

2. The measuring system according to claim 1, wherein the at least one mobile device comprises a mobile phone, a tablet computer, any kind of virtual or augmented reality device such as virtual reality glasses or augmented reality glasses, or a combination thereof.

3. The measuring system according to claim 1, wherein the connection between the measuring device and the at least one mobile device is a wireless connection.

4. The measuring system according to claim 1, wherein the at least one mobile device recognizes or marks at least one probe of the measuring device in the displayed live view of the measurement setup superimposed on the at least one measurement result of the measuring device.

5. The measuring system according to claim 4, wherein the at least one mobile device associates the at least one probe of the measuring device with at least one corresponding measurement result of the measurement results of the measuring device.

6. The measuring system according to claim 1, wherein the measuring device comprises geolocation means for determining a recent position.

7. The measuring system according to claim 1, wherein the at least one mobile device comprises geolocation means for determining a recent position.

8. The measuring system according to claim 1, wherein the measuring device comprises voice control means for controlling at least one function of the measuring device by voice.

9. The measuring device according to claim 1, wherein the at least one mobile device comprises voice control means for controlling at least one function of the at least one mobile device or at least one function of the measuring device.

10. A measuring method comprising the steps of:
measuring data with respect to a measurement setup with the aid of a measuring device, and
displaying a live view of the measurement setup superimposed on at least one measurement result of the measuring device with the aid of at least one mobile device connected to the measuring device.

11. The measuring method according to claim 10, wherein the at least one mobile device comprises a mobile phone, a tablet computer, any kind of virtual or augmented reality device such as virtual reality glasses or augmented reality glasses, or a combination thereof.

12. The measuring method according to claim 10, wherein the connection between the measuring device and the at least one mobile device is a wireless connection.

13. The measuring method according to claim 10, further comprising the step of:
recognizing or marking at least one probe of the measuring device in the displayed live view of the measurement setup superimposed on the at least one measurement result of the measuring device.

14. The measuring method according to claim 13, further comprising the step of:
associating the at least one probe of the measuring device with at least one corresponding measurement result of the at least one measurement result of the measuring device.

15. The measuring method according to claim 10, further comprising the step of:
determining a recent position with the aid of the measuring device comprising geolocation means.

16. The measuring method according to claim 10, further comprising the step of:
determining a recent position with the aid of the at least one mobile device comprising geolocation means.

17. The measuring method according to claim 10, further comprising the step of:
controlling at least one function of the measuring device by voice with the aid of the measuring device comprising voice control means.

18. The measuring method according to claim 10, further comprising the step of:
controlling at least one function of the at least one mobile device or of the measuring device by voice with the aid of the at least one mobile device comprising voice control means.
